(19) United States
(12) Patent Application Publication
(10) Pub. No.: US 2025/0216766 A1
(43) Pub. Date: Jul. 3, 2025

(54) REUSE OF RESOLUTION ENHANCEMENT TECHNIQUE (RET) DATA IN RET PROCESSING OF NEW MASK LAYOUTS

(71) Applicant: Intel Corporation, Santa Clara, CA (US)

(72) Inventors: Kshitij Auluck, Hillsboro, OR (US); Reza Rashetnia, Portland, OR (US); Prasad N. Atkar, Portland, OR (US)

(73) Assignee: Intel Corporation, Santa Clara, CA (US)

(21) Appl. No.: 18/397,245

(22) Filed: Dec. 27, 2023

(51) Int. Cl. G03F 1/36; G06F 30/398

(52) U.S. Cl. CPC G03F 1/36; G06F 30/398

(57) ABSTRACT

Determining initial conditions for resolution enhancement technology (RET) processing of a new mask layer comprises reusing RET geometries from layout portions of previously RET-processed mask layers that match layout portions in the new mask layer. If the RET geometries comprise sub-resolution assist features (SRAFs), conflicts between SRAFs corresponding to neighboring matching layout portions can be resolved as part of determining the initial conditions. The initial conditions can also be based on RET geometries generated by machine learning models for layout portions of the new layer that closely match layout portions in previously processed mask layers. Initial conditions for the remaining layout portions in the new mask layer are generated via RET processing. These initial conditions can enable faster RET processing runtime or reduced computing load for a given level of RET processing output quality.

### BACKGROUND

Resolution enhancement techniques (RETs) adjust the design of a mask layout corresponding to an integrated circuit so that features formed in an integrated circuit structure more closely match desired patterns indicated by the mask layout. Optical proximity correction (OPC) and inverse lithography technology (ILT) are two examples of resolution enhancement techniques.

### BRIEF DESCRIPTION OF THE DRAWINGS

FIG. 1A-1C illustrates an example mask layout polygon after optical proximity correction (OPC) and inverse lithography technology (ILT) processing.

FIG. 2 illustrates a first example method of reusing resolution enhancement technique data in resolution enhancement technique processing of a new mask layout.

FIG. 3 is a block diagram of a first example computing system within which the technologies described herein can be utilized.

FIG. 4 illustrates a second example method of reusing resolution enhancement technique data in resolution enhancement technique processing of a new mask layout.

FIG. 5 is a block diagram of a second example computing system within which the technologies described herein can be utilized.

FIG. 6 is a block diagram of an example processor unit to execute computer-executable instructions as part of implementing technologies described herein.

### DETAILED DESCRIPTION

Semiconductor manufacturing has become increasingly complex over the years. Since the turn of the century, minimum feature sizes have shrunk by over an order of magnitude as the industry has progressed from the 130 nm technology node to the 3 nm technology node. Essential to semiconductor manufacturing is the process of photolithography, by which patterns are transferred from a mask (or photomask) onto a wafer. A mask defines the shapes and locations of features to be patterned in a layer of an integrated circuit structure being fabricated on a wafer. For example, one mask can define where oxide-based isolation regions are to be located, another mask defines where high-k dielectrics will be located, another mask defines the location of transistor source and drain regions, and yet another mask defines where contacts will be placed. Additional masks are used to define metal layers and intervening via layers. The manufacture of advanced integrated circuits can require dozens of masks, and in some cases, up to 100 masks.

As masks are how features in integrated circuit structures are realized, an integrated circuit design must ultimately be reduced to a physical design, the level of design abstraction from which masks are generated. The physical design of a transistor, circuit, processor, etc. to be manufactured is often referred to as a “layout” or “mask layout”. As will be discussed in more detail below, a mask layout comprises multiple mask layers, and a single mask layer can be referred to as a “layer of a mask layout” or a “mask layer”. Electronic design automation (EDA) tools allow processor architects and circuit designers to develop integrated circuit designs at levels of abstraction above the physical design level and are thus spared from having to spend their days drawing polygons in layout tools to realize their designs. Architects typically define their designs using a hardware design language (HDL), such as VHDL or Verilog. Once they have verified that their designs perform as desired, a physical design can be generated automatically, typically by using a library of standard cell layouts. Circuit designers often seek performance or functionality not available using standard cells and often enter their designs into a schematic capture tool. Once their custom designs are finalized, the circuit schematics are handed off to layout designers who manually craft custom physical designs.

Regardless of whether a physical design is generated automatically or manually, it must conform to a set of mask layout design rules established for a manufacturing process. Design rules represent a trade-off between feature density and manufacturability. Being able to print smaller feature sizes can mean more dies can be packed onto a wafer but if the process cannot reliably print the smaller features, the resulting reduction in wafer yield can more than offset the cost reductions gained by being able to print more dies on a wafer.

Once a physical design is cleared of design rule violations and has passed other design validation checks, it is passed to the mask generation phase of an EDA flow. The minimum feature size that can be printed clearly in a photolithographic process is limited by the wavelength of the light source used and the semiconductor industry has developed resolution enhancement technologies (RETs) to allow for the printing of features smaller than the wavelength of light used in photolithographic processes.

Some RETs are applied to mask layouts to have patterns formed in integrated circuit structures more closely resemble the desired patterns represented by the mask layout. Optical proximity correction (OPC) is one RET in which polygons in a mask layout are altered to compensate for image errors due to diffraction or other processing effects. OPC can use a rule-based or compact model approach (or a combination of the two) to determine how polygons are to be altered. Existing polygons in a mask layout can be altered through the addition of polygons to the existing polygons that are generated by compact models or pre-determined polygons based on existing polygon shape, size, and/or spacing to neighboring polygons. OPC can be considered to be an edge-based approach as it results in edges or portions of edges in mask polygons in a mask layout being moved or rectilinear polygons being added to the original polygons in a mask layout.

In addition to altering existing mask layout polygons, OPC approaches can comprise adding sub-resolution assist features (SRAFs) to a mask layout. SRAFs are features added to a mask layout that are separate from the original mask layout polygons. SRAFs are too small to be captured in developed photoresist during a photolithography process, but they aid in forming desired photoresist patterns by providing constructive or destructive interference to light passing through or being reflected by a mask due to optical diffraction at their edges.

Inverse lithography technology (or technique) (ILT) is another resolution enhancement technique. The “inverse” in ILT captures the approach taken by ILT to determine the shapes and sizes of mask layer polygons, by iteratively adjusting mask layer polygon sizes and shapes based on how mask layer polygon shape and size adjustments in an ILT iteration effect predicted photoresist contour characteristics. ILT is computationally intensive as the process of adjusting mask layout polygon shapes based on the output of an ILT run is performed iteratively until photoresist contours predicted by an ILT run are within an acceptable tolerance of a desired pattern indicated in the mask layout. In contrast to OPC, ILT can be considered to be a curvilinear pixel-based approach in that adjustments to mask layout polygons and added SRAFs are not restricted to being rectilinear and are mapped to “pixels” of the mask layer for mask manufacturability purposes. Despite ILT being generally more computationally expensive and producing more complex mask layout designs than OPC, advances in computation power available to EDA software tool vendors and mask-making vendors, as well as the advent of multi-beam mask-making tools, which can greatly reduce the time it takes to write a pattern to a mask, is making ILT an attractive alternative to OPC for use in mask generation for advanced technology nodes.

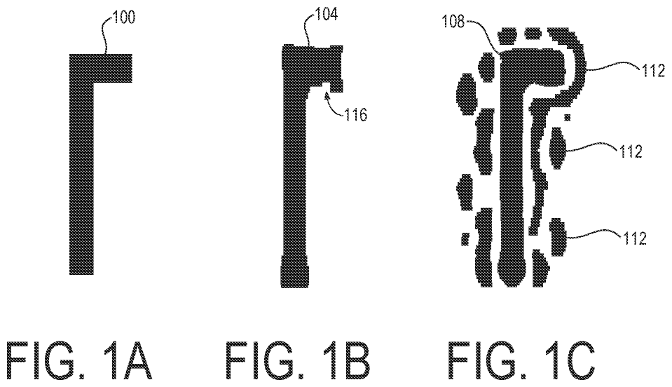

FIG. 1A-1C illustrates an example mask layout polygon after optical proximity correction (OPC) and inverse lithography technology (ILT) processing. FIG. 1A illustrates a polygon 100 in a mask layout prior to RET processing. FIGS. 1B-1C illustrate polygons 104 and 108, which are versions of the original polygon 100 after being processed by OPC and ILT approaches, respectively. FIG. 1C further illustrates example SRAF features 112 corresponding to polygon 108.

Despite advances in computing capability over the years, generating RET geometries for a full set of mask layers in a mask layout for a production integrated circuit is still a computationally arduous undertaking. As mentioned above, integrated circuit designs fabricated with advanced technology nodes can have mask layouts with a large number of layers. Some of these layers may undergo multiple revisions (or steppings) as an integrated circuit product goes through development, and RET processing involving ILT processing may be used for the layer having the smallest critical dimensions. Thus, a large number of mask layers may need to undergo RET processing, which can involve ILT techniques for multiple layers, in a production integrated circuit design.

Described herein are technologies that can determine initial conditions for RET processing of a mask layer of a new mask layout to reduce RET processing time of the new mask layer. For layout portions of the new mask layer that match a layout portion of a mask layer that has already been subjected to RET processing, initial conditions for the matching layout portions of the new mask layer are based on RET geometries previously generated for the previously processed layout portion. Thus, previously generated RET geometries are being reused. If the previously generated RET geometries comprise SRAFs, reused SRAFs associated with neighboring matching layout portions in the new layer may conflict with each other, and SRAF conflict resolution can be performed as part of determining the initial conditions for matched layout portions.

For layout portions of the new mask layer that are a close match (but not an exact match) of previously processed layout portions, information indicating the closely matching mask layout portions is fed into a machine learning model to generate RET processing initial conditions for the closely matching layout portions. Matched and closely matching layout portions of the new mask layer can account for a large portion of the area of a new mask layer, up to 99% or more in some cases. RET processing is performed on the remaining layout portions of the new mask layer to generate RET processing initial conditions for these layout portions.

The technologies disclosed herein have at least the following advantages. By determining initial conditions for RET processing of a new mask layer as disclosed herein, RET processing should consume fewer computing resources relative to RET processing runs for which initiation conditions have not been determined as disclosed herein. If RET processing utilizes ILT techniques, the RET processing can converge in fewer iterations for a given level of quality (as measured by, for example, RET validation software using wafer validation metrics). Or, for a given number of iterations, a higher quality of RET geometries can be obtained. Further, as the technologies described herein provide for the same initial conditions to be used for all instances of a layout portion across a mask layer, it can provide for more consistent RET geometries for instances of the layout portion to be generated across the new mask layer. Reduction in RET geometry variability of a layout portion over a single mask layer can improve manufacturability. Although primarily discussed in the context of ILT approaches, the technologies disclosed herein can also be used for RET processing that comprises OPC approaches.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the terms “operating”, “executing”, or “running” as they pertain to software or firmware in relation to a system, device, platform, or resource are used interchangeably and can refer to software or firmware stored in one or more computer-readable storage media accessible by the system, device, platform or resource, even though the software or firmware instructions are not actively being executed by the system, device, platform, or resource.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

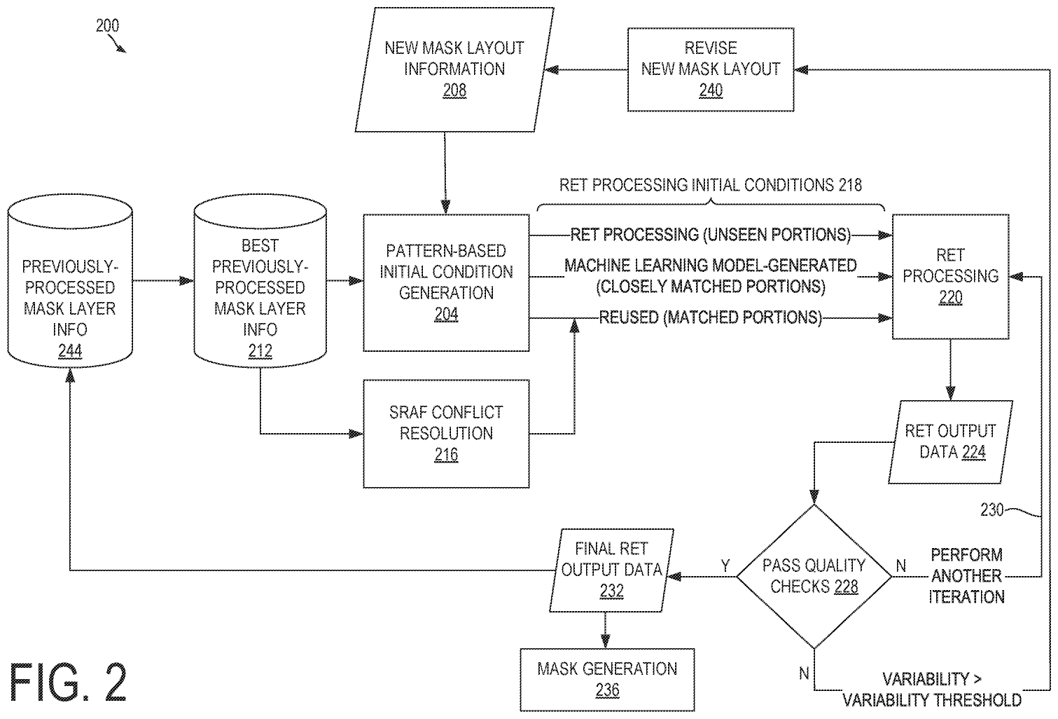

FIG. 2 illustrates a first example method of reusing resolution enhancement technique data in resolution enhancement technique processing of a new mask layout. Method 200 can be performed by, for example, an EDA software tool. At 204, initial conditions are generated for RET processing of a mask layer of a new mask layout (which can be referred to herein as a “new mask layer”) of an integrated circuit design. The new mask layout is represented by new mask layout information 208, which can comprise any suitable data structure or file format, such as OASIS or GDSII. A new mask layer or a new mask layout is “new” in that it has not been subjected to RET processing. In some embodiments, a new mask layer to be subjected to RET processing can comprise multiple instances of an integrated circuit design. This can occur when the size of an integrated circuit design is small enough that the printable area of the mask can accommodate multiple instances of the integrated circuit design.

Initial conditions for RET processing of the new mask layer are generated for three types of portions of the new mask layer (which are also referred to herein as “layout portions”)—layout portions that match layout portions in a mask layer for which RET processing has already been performed (referred to herein as “matching layout portions” or “matched layout portions”), layout portions that closely (but do not exactly) match layout portions in a mask layer for which RET processing has already been performed (referred to herein as “closely matching layout portions”), and layout portions that do not exactly or closely match layout portions in a mask layer for which RET processing has already been performed (referred to herein as “previously unseen layout portions”). A previously RET-processed mask layer that has been subjected to RET processing can be referred to herein as a “previously RET-processed mask layer” or “previously process mask layer”, and layout portions of a previously RET-processed mask layer that has been subjected to RET processing can be referred to herein as a “previously RET-processed layout portion” or a “previously processed layout portion”. A layout portion can be referred to as a layout neighborhood. The physical extent of a layout portion can be defined by the physical extent of a standard cell or other integrated circuit building block comprising the layout portion (e.g., memory bit cell) or by a bounding box of a set size (e.g., a square having a width of 200 microns).

Regardless of how the size of a layout portion is defined, matching a layout portion of a new mask layer with a layout portion in a previously processed mask layer can comprise matching polygons between the two mask layers. While this can involve a large amount of polygon matching to find matching layout portions in the new mask layer, the cost of finding matching layout portions in a new mask layer can be significantly less than performing RET processing on the new mask layer without the benefit of reusing previously-determined RET geometries as initial conditions for the RET processing.

The matching layout portions of the new mask layer are identified by determining which layout portions of the new layer match those of a previously RET-processed mask layer that corresponds to the same processing layer (e.g., M1, contact) as the new layer. The previously RET-processed mask layers can correspond to any integrated circuit design, such as large production designs or small test layouts. A layout portion comprises the polygons in a local region of a mask layer. In some embodiments, a layout portion can comprise all of the polygons of a mask layer in an area having a length and a width in the range of 100 to 250 nanometers.

Information representing previously processed layout portions is stored in a database 212 that stores information representing the best previously processed mask layout portions for a given mask layer and semiconductor manufacturing technology. Information representing previously processed layout portions can comprise information representing RET geometries applied to polygons in an unprocessed mask layer (a mask layer that has not been subjected to RET processing) as well as RET geometries added to the mask layer that are separate from the original polygons in the mask layer (e.g., SRAFs). The application of RET geometries to mask layout polygons can result in an increase or a decrease in the size of the mask layout polygon. An example of an RET geometry that can result in a decrease in the size of a mask layout polygon is a “mouse bite” geometry. Geometry 116 in FIG. 1B illustrates an example mouse bite RET geometry applied to original polygon 100

The previously processed mask layout portions stored in the database 212 are the “best” previously processed mask layout portions in that the instance of a particular previously processed mask portion stored in the database 212 is the instance that has the best manufacturability among other instances of the particular previously processed mask portions that have been considered for inclusion in the database 212 (e.g., other instances of the particular previously processed mask portions in the same mask layer or different mask layers).

Thus, “best” does not indicate an absolute best in that a previously processed mask portion stored in the database has the absolute best manufacturability. It instead represents a relative best among instances of the previously processed mask portion that have been considered for storage in database 212. The previously processed mask portions stored in the database 212 can represent the best RET-processed mask portions out of a large sample size as a single mask layer can comprise several hundreds of thousands of instances of a single mask portion and a large portion of this multitude of instances can have different RET geometries due to RET geometries being able to influence photoresist development over distances (e.g., up to 1.5 microns) that are greater than the widths and lengths of mask layout portions (e.g., in the range of 100 to 250 nanometers).

In some embodiments, the previously processed layout portion stored in the database 212 has a best manufacturability in that it has a lowest error with respect to one or more image and objectives and one or more wafer contour objectives among other instances of the particular previously processed mask portions that have been considered for inclusion in the database 212.

Image objectives are aerial image intensities at different focus settings which correspond to statistical open or short circuit failure modes. These image intensities are simulated image intensities that are generated during RET processing. A first set of image objectives are photoresist scum objects, which are image intensity specifications that are to be met inside a polygon to prevent photoresist residue (scumming) formation after photoresist development. Photoresist scumming in areas where it should be completely removed can create manufacturability issues, such as causing vias to not electrically connect with metal lines, which can cause open circuit failures. A second set of image objectives is top-loss objectives, which are image intensity specifications that are to be met between two neighboring polygons to prevent loss of photoresist after development. Removal of photoresist in undesired areas can introduce spurious vias and cause short-circuiting of metal layers.

Wafer contour objectives in RET processing are specified as tolerances for photoresist contours formed on a wafer. The photoresist contour characteristics used in evaluating whether wafer contour objectives are met are based on simulated photoresist contours. These simulated photoresist contours can be obtained from a lithography model calibrated using actual photoresist contours imaged by RET-corrected masks and extracted from image data (e.g., SEM (scanning electron microscopy) data). These wafer contour specifications correspond to the failure risks of via coverage (insufficient via coverage by a metal layer), and via-to-metal and metal-to-metal shorts. Wafer contour objectives can comprise, for example, deviation tolerances that specify the permissible error between a target edge (the edge of a polygon desired to be formed on a wafer) and the corresponding photoresist edge formed on the wafer, pinch tolerances that specify the closest distance permissible between photoresist contour edges belonging to the same photoresist contour, and bridge tolerances that specify the closest distance permissible between photoresist contour edges belonging to neighboring photoresist contours.

For the best previously processed layout portions, if the previous RET processing comprised generating SRAFs, the database 212 can further comprise information representing SRAFs added to previously processed layout portions.

The RET geometries generated for previously processed layout portions that match layout portions in a new mask layer are used as the basis for initial conditions for each instance of the matching layout portion in the new mask layer. In embodiments where the previously determined RET geometries include SRAFs, the SRAFs to be used as part of the basis for initial conditions for a first matching layout portion can conflict with the SRAFs to be used as part of the basis for initial conditions for a neighboring second matching layout portion. The SRAFs associated with the first and second matching layouts can conflict in that, for example, one or more of the SRAFs corresponding to the first matching layout portion can physically overlap with one or more of the SRAFs corresponding to the second matching portion. In another example, SRAFs associated with the first and second matching layouts can conflict in that one or more of the SRAFs corresponding to the first matching layout portion extends into a region defined by an extent of the plurality of SRAFs corresponding to the second matching layout, or vice versa. The SRAFs to be used as part of the initial conditions for the first and second matching layout portions that conflict with each other can be referred to as a conflicting set of SRAFs.

Resolution of SRAF conflicts is performed at 216 in the method 200. SRAF conflicts can be resolved by having the initial conditions for the new mask layer not be based on the SRAFs associated with the first matching layout portion or the SRAFs associated with the second matching layout portion. SRAF conflicts are not limited to two pluralities of SRAFs conflicting. SRAF conflicts can comprise SRAF pluralities corresponding to three or more matching layout portions and such SRAF conflicts can be resolved in a manner similar to how conflicts involving two pluralities of SRAFs are resolved. That is, an SRAF configuration having a lowest cost can be selected as the resolution to the SRAF conflict, where the various SRAF configurations have one or more of the conflicting pluralities of SRAFs removed from the conflicting set of SRAFs.

In some embodiments, resolving an SRAF conflict can comprise evaluating multiple different SRAF configurations of the conflicting set of SRAFs in which the SRAFs corresponding to one or more of the matching layout portions are removed from the conflicting set of SRAFs. The SRAF configurations are evaluated using an SRAF conflict resolution algorithm that determines a “cost” for the individual SRAF configurations, with the cost of an individual SRAF configuration reflecting a total reduction in image objectives and wafer contour objectives that are satisfied for the individual SRAF configuration. The initial conditions for RET processing of the new mask layer depend on the SRAF configuration having the lowest cost.

The second type of layout portions in a new mask layer for which initial conditions are determined are closely matching layout portions. Closely matching layout portions are layout portions in the new mask layer that are not exact matches for previously processed layout portions stored in database 212, but for which at least one polygon edge in the closely matching layout portion is spaced from a corresponding edge of a corresponding polygon of a previously processed layout portion within a threshold distance. In some embodiments, this threshold distance can be 50 nanometers or less, such as 10 nm, 20 nm, 30 nm, 40 nm, or 50 nm. In some embodiments, a closely matching layout portion can exactly match a previously processed layout portion except for the closely matching layout portion having one or more polygons that are shifted from corresponding polygons in the previously processed layout portion, the closely matching layout portion having one or more extra polygons relative to the previously processed layout portion, the closely matching layout portion missing one or more polygons relative to a previously processed layout portion, or a combination thereof.

Once closely matching layouts in the new mask layer are identified, initial conditions for RET processing of the new mask layer for the closely matching layouts are generated using a machine learning model. The machine learning model can be provided with a layout portion as input and generate RET geometries for the layout portion and/or initial conditions for RET processing as output. The machine learning model can be trained using information representing mask steppings of a mask layer as training inputs to the machine learning model and information representing RET geometries corresponding to the mask steppings as training outputs of the machine learning model. A mask stepping comprises revisions to a mask layer relative to a prior version of the mask layer captured in the previous mask stepping. Thus, a set of mask steppings captures a series of revisions to an original mask layout, with each stepping containing one or more revisions to the previous version of the mask layout. The revisions to a mask layout are typically minor and can capture changes such as tweaks to standard logic cells to implement a desired change. For example, an original version of a mask layout can be referred to as an “A0” stepping of the layout, a “B0” stepping can contain a set of revisions made to the original layout, and a “B1” stepping of the mask layout can contain a set of revisions made to the B0 stepping. Thus, a machine learning model that generates RET geometries for mask layout portions that has been trained on mask layouts having only minor variations may be able to generate RET geometries that provide the basis for good RET processing initial conditions for closely matching layout portions in the new mask layer.

The third type of layout portion in a new mask for which initial conditions are determined are previously unseen layout portions. Previously unseen layout portions are layout portions of the new mask layer that do not match (either exactly or closely) previously processed layout portions. Initial conditions for the previously unseen layout portions are generated based on RET processing of the previously unseen layout portions. The area occupied by previously unseen layout portions in a new mask layer can be relatively small compared to the overall total area of the new mask layer. In some cases, previously unseen layout portions can comprise 1% or less of the area of a new mask layout. The number of unique previously unseen layout portions can occupy an even smaller portion of the area of a new mask layout as a new mask layer can contain many instances of previously unseen layout portions. Thus, performing RET processing on the unique previously unseen layout portions is not likely to offset the reduction in computational resources needed to perform RET processing of a new mask layer that reuses previously generated RET geometries. The initial conditions for previously unseen layout portions are determined from the RET geometries produced by RET processing of the previously unseen layout portions.

It is to be noted that determining initial conditions for RET processing of a new mask layer can comprise determining initial conditions for only the unique layout portions in the mask layer. Mask layout portions, such as those associated with standard logic cells or memory bit cells, can be repeated extensively in a mask layer. Thus, determining initial conditions for just unique layout portions can save a large amount of computing effort. Further, in some embodiments, information representing RET geometries can be used as initial conditions for RET processing and there is no conversion of information representing RET geometries to initial condition information to be used in RET processing.

Once initial conditions 218 have been determined for all layout portions in a new mask layer, RET processing of the new mask layer is performed at 220. RET processing of the new mask layer can utilize ILT techniques and having initial conditions for the layout portions of the new mask layer can result in the generation of higher quality RET geometries, reduced computation load or runtime, or a combination thereof. For example, RET processing comprising ILT techniques having initial conditions for the layout portions in the new mask that have been determined as described herein can converge in fewer iterations to achieve a given level of quality in the RET output 224 relative to RET processing runs not reusing RET geometries, or result in higher quality RET output 224 using the same amount of computing resources or taking the same amount of runtime relative to RET processing runs that did not have initial conditions determined as described herein. In some embodiments, the quality of RET output 224 generated by RET processing can be measured against one or more of the image objectives and/or one or more of the wafer contour objectives described above.

RET processing of a new mask layer at 220 generates RET output 224, which comprises RET geometries that are to be applied to polygons in the new mask layer and, in some embodiments, as well as SRAFs that are to be added to the new mask layer. The RET output 224 can also comprise additional information, such as characteristics of predicted photoresist contours in a photolithography process using the RET-processed new mask layer. In ILT-based RET processing, multiple RET processing runs can be performed before RET processing converges to a final result and successive RET processing iterations can be at least partially based on RET data generated from a previous run, as indicated by arrow 230 in FIG. 2.

In some embodiments, even though a large portion of a new mask layer may comprise matching layout portions, it may take several iterations of ILT-based RET processing for the ILT processing to converge. This can be the result of RET geometries in mask layout portions influencing the optical behavior of adjacent layout portions, and several iterations of RET processing may be needed to resolve these interactions.

In some embodiments, RET processing of a new mask layer can be performed hierarchically and/or in parallel, with RET processing for a mask layer being performed first on smaller layout portions of the new layer, and then on larger portions of the new mask layer, with RET processing of individual layout portions of the new mask layer being performed in parallel in a computing system capable of distributed computing.

After RET output 224 for an RET processing run is generated, the RET output one or more quality checks are performed at 228 on the RET output 224. If the RET output 224 passes the quality checks, the RET output 224 can be considered to be finalized (final RET output 232) and used in mask generation at 236.

In some embodiments, the quality checks performed at 228 can comprise evaluating the RET output 224 against one or more of the image and/or wafer contour objectives discussed above. If the RET output 224 does not meet any of the objectives it is checked again, another RET processing iteration may be performed.

In some embodiments, the quality checks can measure the variability in predicted photoresist contours. It is advantageous in advanced semiconductor manufacturing technology nodes to have a low amount of variability in features across a wafer in various particular processing steps. Thus, a variability check performed at 228 can comprise determining the variability of one or more predicted photoresist features in the RET output 224 across a wafer. The variability check can determine how much a position of a predicted photoresist contour relative to its associated polygon in the new mask layer, a width of a photoresist feature, a spacing between adjacent photoresist features, etc., varies across a wafer. If the variability of the one or more predicted photoresist features is less than a variability threshold, the RET output passes the variability check. If not, the layout of the mask layout may be revised at 240 and initial conditions may be generated again at 204 based on the revised new mask layout before RET processing is performed at 220 on the revised new mask layout. The cycle of revising a new mask layout to address the variability in photoresist contours across a new mask design being too great, generating new initial conditions based on the revised new mask layout, and performing RET processing on the revised new mask layout and with updated initial conditions can be performed iteratively until an acceptable amount of variability is obtained.

Once RET processing at 220 of a new mask layer has resulted in RET output 224 that passes quality checks at 228, the resulting final RET output 232 can be sent to a mask-making tool to generate a mask at 236. The mask-making tool can utilize the information representing the mask layer and the information representing the RET geometries corresponding to the mask layer in the final RET output 232 to generate a mask.

Information representing an RET-processed new mask layer and information representing the RET geometries to be applied to or added to the new mask layer can be stored in a database 244 that stores information for previously processed mask layers. In some embodiments, information indicating the performance of individual layout portions of a mask layer and/or for the full mask layer against one or more image objectives and one or more wafer contour objectives can be stored in the database 244 along with the information indicating the mask layer.

In some embodiments, once RET processing for a new mask layer has been finalized for use in generating a mask, layout portions of the RET-processed new mask layer can be evaluated for addition into database 212, the database comprising “best” previously processed layout portions. If an instance of a particular layout portion of an RET-processed new mask layer is “better” than the version of the previously processed layout portion stored in database 212 (with “better”, as discussed above, meaning that it has a lower error with respect to image and wafer contour objectives), the database 212 is updated with information representing the RET-processed instance of the particular layout portion of the new mask layer replacing the information representing the instance of the particular layout portion in the database 212 that previously had the “best” RET geometries.

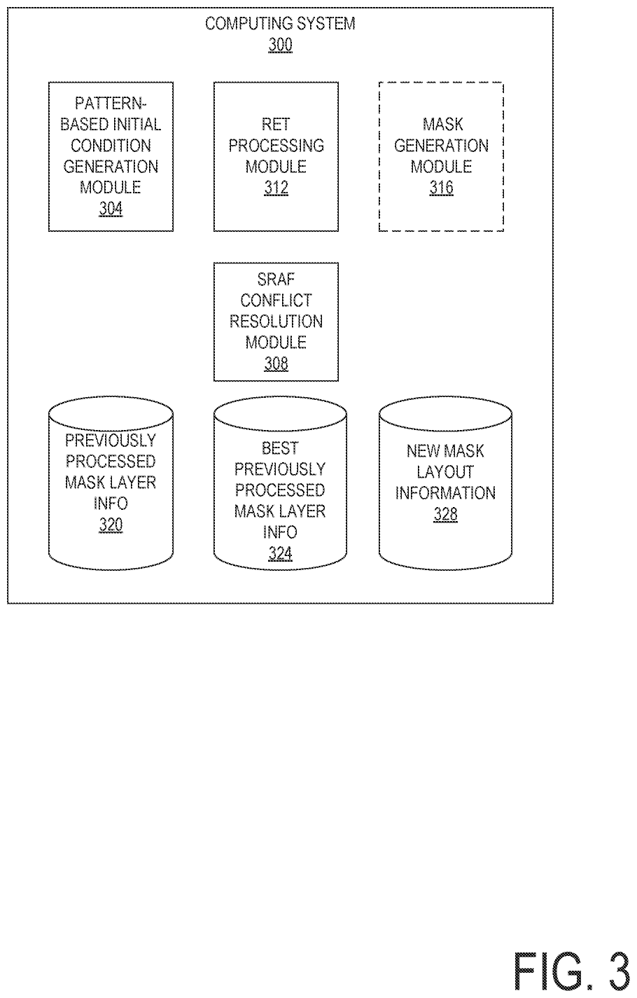

FIG. 3 is a block diagram of a first example computing system within which the technologies described herein can be utilized. The computing system 300 comprises a pattern-based initial condition generation module 304, an SRAF conflict resolution module 308, and an RET processing module 312. The computing system 300 further comprises a previously processed mask layer information store 320, a best previously processed mask layer information store 324, and a new mask layout information store 328. The previously processed mask layer information store 320 can implement the database 244 and the best previously processed mask layer information store 324 can implement the database 212. Any of the databases or stores described or referenced herein can comprise one or more of any type of data structure or file format.

The pattern-based initial condition generation module 304 generates initial conditions for RET processing of a new mask layout represented by information in the new mask layout information store 328 for layout portions of the new mask layer that either match, closely match, or do not match layout portions of previously processed mask layer represented by information stored in the best previously processed mask layer information store 324. The initial conditions for matched layout portions are based on RET geometries corresponding to a previously processed mask layout in the best previously processed mask layer information store 324. The SRAF conflict resolution module 308 resolves SRAF conflicts between SRAFs corresponding to physically adjacent matched layout portions in the new mask layer. The RET processing module 312 determines RET geometries and predicted photoresist contours for a new mask layer using the initial conditions generated by the pattern-based initial condition generation module 304.

The computing system 300 can be any computing system described or referenced herein, or any other computing system. In some embodiments, the modules 304, 308, and 312 can be part of an EDA software tool. In embodiments where the computing system 300 is a mask-making tool, the computing system 300 can further comprise a mask generation module 316 that causes the mask-making tool to generate a mask based on new mask layer information stored in the new mask layout information store 328 and final RET output data produced by RET processing of the new mask layer. The stores 320, 324, and 328 can be any memory or storage described or referenced herein, or any other memory or storage. In some embodiments, all or a part of any of the stores 320, 324, and 328 can be internal, external, or remote to the computing system 300.

It is to be understood that FIG. 3 illustrates one example of a set of modules that can be included in a computing system. In other embodiments, a computing system can have more or fewer modules than those shown in FIG. 3. Further, separate modules can be combined into a single module, and a single module can be split into multiple modules. The modules shown in FIG. 3 can be implemented in software, hardware, firmware, or combinations thereof.

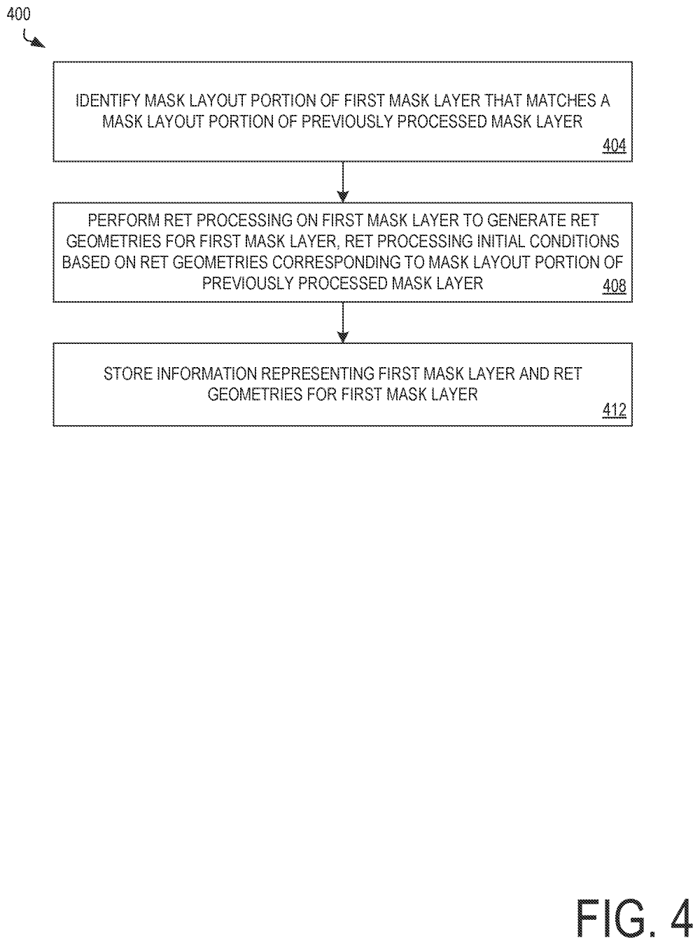

FIG. 4 illustrates a first example method of reusing resolution enhancement technique data in resolution enhancement technique processing of a new mask layout. The method 400 can be performed by an EDA software tool. At 404, a mask layout portion of a first mask layer that matches a mask layout portion of a second mask layer is identified, the first mask layer corresponding to an integrated circuit design, the second mask layer a previously resolution enhancement technique (RET)-processed mask layer. At 408, RET processing on the first mask layer to generate a plurality of RET geometries for the first mask layer is performed, initial conditions for RET processing of the first mask layer based on a plurality of RET geometries corresponding to the mask layout portion of the second mask layer. At 412, information representing the first mask layer and information representing the plurality of RET geometries for the first mask layer is stored.

In other embodiments, the method 400 can further comprise one or more additional elements. For example, wherein the mask layout portion of the first mask layer is a first mask layout portion of the first mask layer, the mask layout portion of the second mask layer is a first mask layout portion of the second mask layer, the plurality of RET geometries corresponding to the first mask layout portion of the second mask layer is a first plurality of RET geometries, the first plurality of RET geometries comprising a first plurality of SRAFs, the method 400 can further comprise identifying one or more second mask layout portions of the first mask layer that match one or more second mask layout portions of the second mask layer, second pluralities of RET geometries corresponding to the one or more second mask layout portions of the second mask layer comprising one or more second pluralities of SRAFs; and determining that a conflict exists between the first plurality of SRAFs and the one or more second pluralities of SRAFs, wherein, to resolve the conflict, the initial conditions for RET processing of the first mask layer are not based on the first plurality of SRAFs and/or at least one of the one or more second pluralities of SRAFs.

The technologies described herein can be performed by or implemented in any of a variety of computing systems, including mobile computing systems (e.g., handheld computers, tablet computers, laptop computers, 2-in-1 convertible computers, portable all-in-one computers), non-mobile computing systems (e.g., desktop computers, servers, workstations, rack-level computing solutions (e.g., blade, tray, or sled computing systems)), and embedded computing systems (e.g., computing systems that are part of manufacturing equipment, such as a mask-making tool). As used herein, the term “computing system” includes computing devices and includes systems comprising multiple discrete physical components. In some embodiments, the computing systems are located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

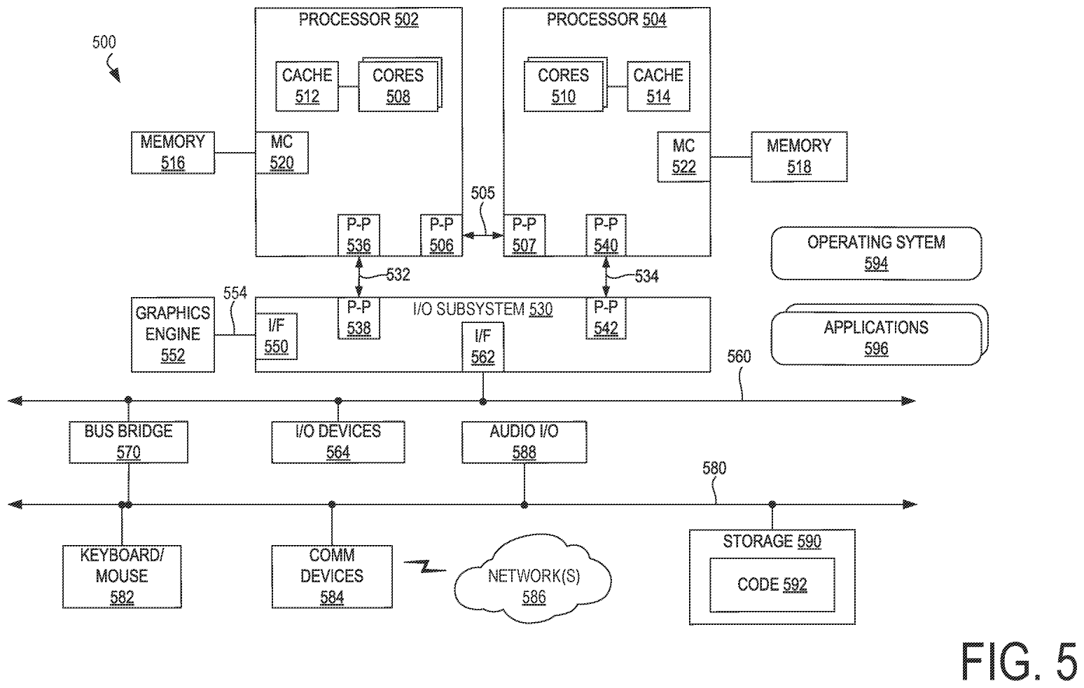

FIG. 5 is a block diagram of a second example computing system in which technologies described herein may be implemented. Generally, components shown in FIG. 5 can communicate with other shown components, although not all connections are shown, for ease of illustration. The computing system 500 is a multiprocessor system comprising a first processor unit 502 and a second processor unit 504 comprising point-to-point (P-P) interconnects. A point-to-point (P-P) interface 506 of the processor unit 502 is coupled to a point-to-point interface 507 of the processor unit 504 via a point-to-point interconnection 505. It is to be understood that any or all of the point-to-point interconnects illustrated in FIG. 5 can be alternatively implemented as a multi-drop bus, and that any or all buses illustrated in FIG. 5 could be replaced by point-to-point interconnects.

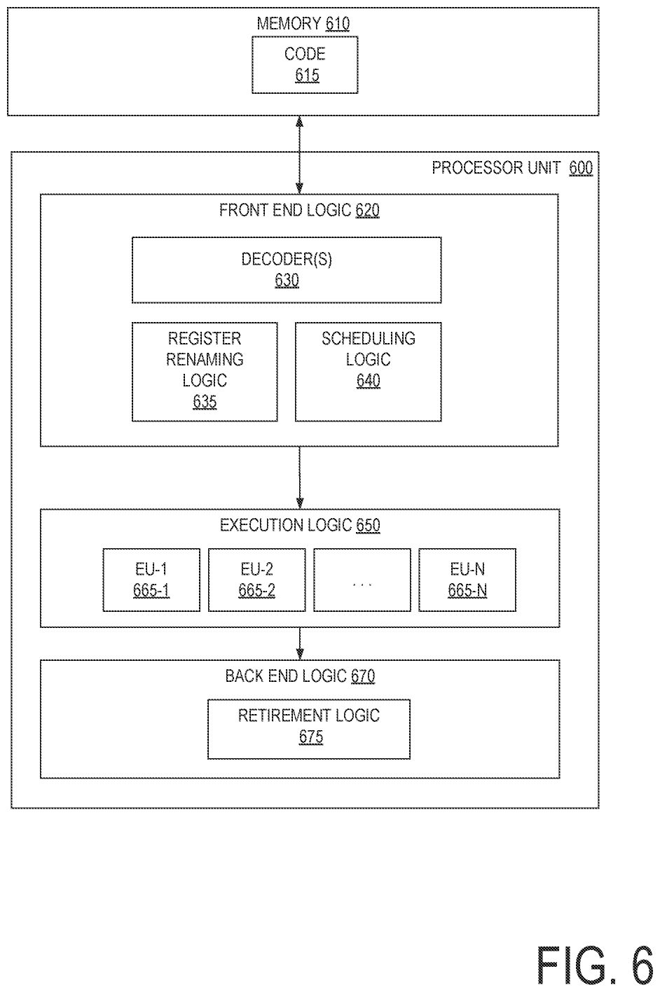

The processor units 502 and 504 comprise multiple processor cores. Processor unit 502 comprises processor cores 508 and processor unit 504 comprises processor cores 510. Processor cores 508 and 510 can execute computer-executable instructions in a manner similar to that discussed below in connection with FIG. 6, or other manners.

Processor units 502 and 504 further comprise cache memories 512 and 514, respectively. The cache memories 512 and 514 can store data (e.g., instructions) utilized by one or more components of the processor units 502 and 504, such as the processor cores 508 and 510. The cache memories 512 and 514 can be part of a memory hierarchy for the computing system 500. For example, the cache memories 512 can locally store data that is also stored in a memory 516 to allow for faster access to the data by the processor unit 502. In some embodiments, the cache memories 512 and 514 can comprise multiple cache levels, such as level 1 (L1), level 2 (L2), level 3 (L3), level 4 (L4) and/or other caches or cache levels. In some embodiments, one or more levels of cache memory (e.g., L2, L3, L4) can be shared among multiple cores in a processor unit or among multiple processor units in an integrated circuit component. In some embodiments, the last level of cache memory on an integrated circuit component can be referred to as a last level cache (LLC). One or more of the higher levels of cache levels (the smaller and faster caches) in the memory hierarchy can be located on the same integrated circuit die as a processor core and one or more of the lower cache levels (the larger and slower caches) can be located on an integrated circuit dies that are physically separate from the processor core integrated circuit dies.

Although the computing system 500 is shown with two processor units, the computing system 500 can comprise any number of processor units. Further, a processor unit can comprise any number of processor cores. A processor unit can take various forms such as a central processing unit (CPU), a graphics processing unit (GPU), general-purpose GPU (GPGPU), accelerated processing unit (APU), field-programmable gate array (FPGA), neural network processing unit (NPU), data processor unit (DPU), accelerator (e.g., graphics accelerator, digital signal processor (DSP), compression accelerator, artificial intelligence (AI) accelerator), controller, or other types of processing units. As such, the processor unit can be referred to as an XPU (or xPU). Further, a processor unit can comprise one or more of these various types of processing units. In some embodiments, the computing system comprises one processor unit with multiple cores, and in other embodiments, the computing system comprises a single processor unit with a single core. As used herein, the terms “processor unit” and “processing unit” can refer to any processor, processor core, component, module, engine, circuitry, or any other processing element described or referenced herein.

In some embodiments, the computing system 500 can comprise one or more processor units that are heterogeneous or asymmetric to another processor unit in the computing system. There can be a variety of differences between the processing units in a system in terms of a spectrum of metrics of merit including architectural, microarchitectural, thermal, power consumption characteristics, and the like. These differences can effectively manifest themselves as asymmetry and heterogeneity among the processor units in a system.

The processor units 502 and 504 can be located in a single integrated circuit component (such as a multi-chip package (MCP) or multi-chip module (MCM)) or they can be located in separate integrated circuit components. An integrated circuit component comprising one or more processor units can comprise additional components, such as embedded DRAM, stacked high bandwidth memory (HBM), shared cache memories (e.g., L3, L4, LLC), input/output (I/O) controllers, or memory controllers. Any of the additional components can be located on the same integrated circuit die as a processor unit, or on one or more integrated circuit dies separate from the integrated circuit dies comprising the processor units. In some embodiments, these separate integrated circuit dies can be referred to as “chiplets”. In some embodiments where there is heterogeneity or asymmetry among processor units in a computing system, the heterogeneity or asymmetric can be among processor units located in the same integrated circuit component. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Processor units 502 and 504 further comprise memory controller logic (MC) 520 and 522. As shown in FIG. 5, MCs 520 and 522 control memories 516 and 518 coupled to the processor units 502 and 504, respectively. The memories 516 and 518 can comprise various types of volatile memory (e.g., dynamic random-access memory (DRAM), static random-access memory (SRAM)) and/or non-volatile memory (e.g., flash memory, chalcogenide-based phase-change non-volatile memories), and comprise one or more layers of the memory hierarchy of the computing system. While MCs 520 and 522 are illustrated as being integrated into the processor units 502 and 504, in alternative embodiments, the MCs can be external to a processor unit.

Processor units 502 and 504 are coupled to an Input/Output (I/O) subsystem 530 via point-to-point interconnections 532 and 534. The point-to-point interconnection 532 connects a point-to-point interface 536 of the processor unit 502 with a point-to-point interface 538 of the I/O subsystem 530, and the point-to-point interconnection 534 connects a point-to-point interface 540 of the processor unit 504 with a point-to-point interface 542 of the I/O subsystem 530. Input/Output subsystem 530 further includes an interface 550 to couple the I/O subsystem 530 to a graphics engine 552. The I/O subsystem 530 and the graphics engine 552 are coupled via a bus 554.

The Input/Output subsystem 530 is further coupled to a first bus 560 via an interface 562. The first bus 560 can be a Peripheral Component Interconnect Express (PCIe) bus or any other type of bus. Various I/O devices 564 can be coupled to the first bus 560. A bus bridge 570 can couple the first bus 560 to a second bus 580. In some embodiments, the second bus 580 can be a low pin count (LPC) bus. Various devices can be coupled to the second bus 580 including, for example, a keyboard/mouse 582, audio I/O devices 588, and a storage device 590, such as a hard disk drive, solid-state drive, or another storage device for storing computer-executable instructions (code) 592 or data. The code 592 can comprise computer-executable instructions for performing methods described herein. Additional components that can be coupled to the second bus 580 include communication device(s) 584, which can provide for communication between the computing system 500 and one or more wired or wireless networks 586 (e.g. Wi-Fi, cellular, or satellite networks) via one or more wired or wireless communication links (e.g., wire, cable, Ethernet connection, radio-frequency (RF) channel, infrared channel, Wi-Fi channel) using one or more communication standards (e.g., IEEE 502.11 standard and its supplements).

In embodiments where the communication devices 584 support wireless communication, the communication devices 584 can comprise wireless communication components coupled to one or more antennas to support communication between the computing system 500 and external devices. The wireless communication components can support various wireless communication protocols and technologies such as Near Field Communication (NFC), IEEE 1002.11 (Wi-Fi) variants, WiMax, Bluetooth, Zigbee, 4G Long Term Evolution (LTE), Code Division Multiplexing Access (CDMA), Universal Mobile Telecommunication System (UMTS) and Global System for Mobile Telecommunication (GSM), and 5G broadband cellular technologies. In addition, the wireless modems can support communication with one or more cellular networks for data and voice communications within a single cellular network, between cellular networks, or between the computing system and a public switched telephone network (PSTN).

The system 500 can comprise removable memory such as flash memory cards (e.g., SD (Secure Digital) cards), memory sticks, Subscriber Identity Module (SIM) cards). The memory in system 500 (including caches 512 and 514, memories 516 and 518, and storage device 590) can store data and/or computer-executable instructions for executing an operating system 594 and application programs 596. Example data includes web pages, text messages, images, sound files, video data, and information representing mask layout layers and RET geometries to be sent to and/or received from one or more network servers or other devices by the system 500 via the one or more wired or wireless networks 586, or for use by the system 500. The system 500 can also have access to external memory or storage (not shown) such as external hard drives or cloud-based storage.

The operating system 594 can control the allocation and usage of the components illustrated in FIG. 5 and support the one or more application programs 596. The application programs 596 can include common computing system applications (e.g., email applications, calendars, contact managers, web browsers, messaging applications) as well as other computing applications, such as an EDA applications or applications that control a mask-making tool.

In some embodiments, a hypervisor (or virtual machine manager) operates on the operating system 594 and the application programs 596 operate within one or more virtual machines operating on the hypervisor. In these embodiments, the hypervisor is a type-2 or hosted hypervisor as it is running on the operating system 594. In other hypervisor-based embodiments, the hypervisor is a type-1 or “bare-metal” hypervisor that runs directly on the platform resources of the computing system 594 without an intervening operating system layer.

In some embodiments, the applications 596 can operate within one or more containers. A container is a running instance of a container image, which is a package of binary images for one or more of the applications 596 and any libraries, configuration settings, and any other information that one or more applications 596 need for execution. A container image can conform to any container image format, such as Docker®, Appc, or LXC container image formats. In container-based embodiments, a container runtime engine, such as Docker Engine, LXU, or an open container initiative (OCI)-compatible container runtime (e.g., Railcar, CRI-O) operates on the operating system (or virtual machine monitor) to provide an interface between the containers and the operating system 594. An orchestrator can be responsible for management of the computing system 500 and various container-related tasks such as deploying container images to the computing system 594, monitoring the performance of deployed containers, and monitoring the utilization of the resources of the computing system 594.

The computing system 500 can support various additional input devices, such as a touchscreen, touchpad, or trackpad and one or more output devices, such as one or more displays. Other possible input and output devices include piezoelectric and other haptic I/O devices. Any of the input or output devices can be internal to, external to, or removably attachable with the system 500. External input and output devices can communicate with the system 500 via wired or wireless connections.

It is to be understood that FIG. 5 illustrates only one example computing system architecture. Computing systems based on alternative architectures can be used to implement technologies described herein. For example, instead of the processors 502 and 504 and the graphics engine 552 being located on discrete integrated circuits, a computing system can comprise an SoC (system-on-a-chip) integrated circuit incorporating multiple processors, a graphics engine, and additional components. Further, a computing system can connect its constituent component via bus or point-to-point configurations different from that shown in FIG. 5. Moreover, the illustrated components in FIG. 5 are not required or all-inclusive, as shown components can be removed and other components added in alternative embodiments.

FIG. 6 is a block diagram of an example processor unit 600 to execute computer-executable instructions as part of implementing technologies described herein. The processor unit 600 can be a single-threaded core or a multithreaded core in that it may include more than one hardware thread context (or “logical processor”) per processor unit.

FIG. 6 also illustrates a memory 610 coupled to the processor unit 600. The memory 610 can be any memory described herein or any other memory known to those of skill in the art. The memory 610 can store computer-executable instructions 615 (code) executable by the processor unit 600.

The processor unit comprises front-end logic 620 that receives instructions from the memory 610. An instruction can be processed by one or more decoders 630. The decoder 630 can generate as its output a micro-operation such as a fixed width micro-operation in a predefined format, or generate other instructions, microinstructions, or control signals, which reflect the original code instruction. The front-end logic 620 further comprises register renaming logic 635 and scheduling logic 640, which generally allocate resources and queues operations corresponding to converting an instruction for execution.

The processor unit 600 further comprises execution logic 650, which comprises one or more execution units (EUs) 665-1 through 665-N. Some processor unit embodiments can include a number of execution units dedicated to specific functions or sets of functions. Other embodiments can include only one execution unit or one execution unit that can perform a particular function. The execution logic 650 performs the operations specified by code instructions. After completion of execution of the operations specified by the code instructions, back-end logic 670 retires instructions using retirement logic 675. In some embodiments, the processor unit 600 allows out of order execution but requires in-order retirement of instructions. Retirement logic 675 can take a variety of forms as known to those of skill in the art (e.g., re-order buffers or the like).

The processor unit 600 is transformed during execution of instructions, at least in terms of the output generated by the decoder 630, hardware registers and tables utilized by the register renaming logic 635, and any registers (not shown) modified by the execution logic 650.

As used herein, the term “module” refers to logic that may be implemented in a hardware component or device, software or firmware running on a processor unit, or a combination thereof, to perform one or more operations consistent with the present disclosure. Software and firmware may be embodied as instructions and/or data stored on non-transitory computer-readable storage media. As used herein, the term “circuitry” can comprise, singly or in any combination, non-programmable (hardwired) circuitry, programmable circuitry such as processor units, state machine circuitry, and/or firmware that stores instructions executable by programmable circuitry. Modules described herein may, collectively or individually, be embodied as circuitry that forms a part of a computing system. Thus, any of the modules can be implemented as circuitry, such as RET processing circuitry or initial condition generation circuitry. A computing system referred to as being programmed to perform a method can be programmed to perform the method via software, hardware, firmware, or combinations thereof.

Any of the disclosed methods (or a portion thereof) can be implemented as computer-executable instructions or a computer program product. Such instructions can cause a computing system or one or more processor units capable of executing computer-executable instructions to perform any of the disclosed methods. As used herein, the term “computer” refers to any computing system, device, or machine described or mentioned herein as well as any other computing system, device, or machine capable of executing instructions. Thus, the term “computer-executable instruction” refers to instructions that can be executed by any computing system, device, or machine described or mentioned herein as well as any other computing system, device, or machine capable of executing instructions.

The computer-executable instructions or computer program products as well as any data created and/or used during implementation of the disclosed technologies can be stored on one or more tangible or non-transitory computer-readable storage media, such as volatile memory (e.g., DRAM, SRAM), non-volatile memory (e.g., flash memory, chalcogenide-based phase-change non-volatile memory) optical media discs (e.g., DVDs, CDs), and magnetic storage (e.g., magnetic tape storage, hard disk drives). Computer-readable storage media can be contained in computer-readable storage devices such as solid-state drives, USB flash drives, and memory modules. Alternatively, any of the methods disclosed herein (or a portion) thereof may be performed by hardware components comprising non-programmable circuitry. In some embodiments, any of the methods herein can be performed by a combination of non-programmable hardware components and one or more processing units executing computer-executable instructions stored on computer-readable storage media.

The computer-executable instructions can be part of, for example, an operating system of the computing system, an application stored locally to the computing system, or a remote application accessible to the computing system (e.g., via a web browser). Any of the methods described herein can be performed by computer-executable instructions performed by a single computing system or by one or more networked computing systems operating in a network environment. Computer-executable instructions and updates to the computer-executable instructions can be downloaded to a computing system from a remote server.

Further, it is to be understood that implementation of the disclosed technologies is not limited to any specific computer language or program. For instance, the disclosed technologies can be implemented by software written in C++, C#, Java, Perl, Python, JavaScript, Adobe Flash, C#, assembly language, or any other programming language. Likewise, the disclosed technologies are not limited to any particular computer system or type of hardware.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, cable (including fiber optic cable), magnetic communications, electromagnetic communications (including RF, microwave, ultrasonic, and infrared communications), electronic communications, or other such communication means.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 comprises a method comprising: identifying a mask layout portion of a first mask layer that matches a mask layout portion of a second mask layer, the first mask layer corresponding to an integrated circuit design, the second mask layer a previously resolution enhancement technique (RET)-processed mask layer; performing RET processing on the first mask layer to generate a plurality of RET geometries for the first mask layer, initial conditions for RET processing of the first mask layer based on a plurality of RET geometries corresponding to the mask layout portion of the second mask layer; and storing information representing the first mask layer and information representing the plurality of RET geometries for the first mask layer.

Example 2 comprises the method of Example 1, wherein the plurality of RET geometries corresponding to the mask layout portion of the second mask layer comprises a plurality of sub-resolution assist features (SRAFs).

Example 3 comprises the method of Example 2, wherein the mask layout portion of the first mask layer is a first mask layout portion of the first mask layer, the mask layout portion of the second mask layer is a first mask layout portion of the second mask layer, the plurality of RET geometries corresponding to the first mask layout portion of the second mask layer is a first plurality of RET geometries, the first plurality of RET geometries comprising a first plurality of SRAFs, the method further comprising: identifying one or more second mask layout portions of the first mask layer that match one or more second mask layout portions of the second mask layer, second pluralities of RET geometries corresponding to the one or more second mask layout portions of the second mask layer comprising one or more second pluralities of SRAFs; and determining that a conflict exists between the first plurality of SRAFs and the one or more second pluralities of SRAFs, wherein, to resolve the conflict, the initial conditions for RET processing of the first mask layer are not based on the first plurality of SRAFs and/or at least one of the one or more second pluralities of SRAFs.

Example 4 comprises the method of Example 3, wherein the first plurality of SRAFs conflicts with two or more second pluralities of SRAFs.

Example 5 comprises the method of Example 3 or 4, wherein the first plurality of SRAFs conflicts with the one or more second pluralities of SRAFs in that an SRAF of the first plurality of SRAFs overlaps with an SRAF of the one or more second pluralities of SRAFs.

Example 6 comprises the method of Example 3 or 4, wherein the first plurality of SRAFs conflicts with the one or more second pluralities of SRAFs in that an SRAF of the first plurality of SRAFs extends into a region defined by an extent of one of the one or more second pluralities of SRAFs.

Example 7 comprises the method of any one of Examples 3-6, where the first plurality of SRAFs and the one or more second pluralities of SRAFs define a conflicting set of SRAFs, the method further comprising: determining an SRAF configuration cost for a plurality of SRAF configurations, individual SRAF configurations of the plurality of SRAF configurations comprising the conflicting set of SRAFs with the first plurality of SRAFs and/or at least one of the one or more second pluralities of SRAFs removed from the conflicting set of SRAFs, the individual SRAF configurations comprising a different set of SRAFs, the SRAF configuration cost for an individual SRAF configuration based on one or more image objectives and one or more wafer contour objectives for the individual SRAF configuration; and determining an SRAF configuration from the plurality of SRAF configurations having a lowest SRAF configuration cost, wherein the first plurality of SRAFs and/or the one or more second pluralities of SRAFs that RET processing of the first mask layer is not based on the first plurality of SRAFs and/or the one or more second pluralities of SRAFs removed from the conflicting set of SRAFs for the SRAF configuration having the lowest SRAF configuration cost.

Example 8 comprises the method of Example 7, wherein the one or more image objectives comprise an objective indicating a predicted image intensity that is to be met inside an SRAF to prevent photoresist residue formation after photoresist development.

Example 9 comprises the method of Example 7, wherein the one or more image objectives comprise an objective indicating a predicted image intensity that is to be met between two neighboring SRAFs to prevent loss of a photoresist after development.

Example 10 comprises the method of Example 7, wherein the one or more wafer contour objectives comprise an objective indicating a permissible error between an edge of an SRAF and a corresponding photoresist edge formed on a wafer.

Example 11 comprises the method of Example 7, wherein the one or more wafer contour objectives comprise an objective indicating a closest permissible distance between photoresist contour edges belonging to a same photoresist contour.

Example 12 comprises the method of Example 7, wherein the one or more wafer contour objectives comprise an objective indicating a closest permissible distance between photoresist contour edges belonging to neighboring photoresist contours.

Example 13 comprises the method of Example 1, wherein the mask layout portion of the first mask layer is a first mask layout portion of the first mask layer and the mask layout portion of the second mask layer is a first mask layout portion of the second mask layer, the plurality of RET geometries corresponding to the first mask layout portion of the second mask layer is a first plurality of RET geometries, the method further comprising: identifying a second mask layout portion of the first mask layer that closely matches a second mask layout portion of the second mask layer, wherein the second mask layout portion of the first mask layer closely matches the second mask layout portion of the second mask layer in that at least one edge of a polygon in the second mask layout portion of the first mask layer is spaced a corresponding edge of a corresponding polygon in the second mask layout portion of the second mask layer by a distance within a range of distances; and generating, by providing information representing the second mask layout portion of the first mask layer to a machine learning model, a second plurality of RET geometries corresponding to the second mask layout portion of the first mask layer, wherein the initial conditions for the RET processing of the first mask layer is further based on the second plurality of RET geometries corresponding to the second mask layout portion of the first mask layer.

Example 14 comprises the method of Example 13, wherein the range of distances is one to five nanometers.

Example 15 comprises the method of Example 13, wherein the machine learning model has been trained using information representing mask steppings of a mask layer as input to the machine learning model and information representing RET geometries corresponding to the mask steppings as outputs of the machine learning model.

Example 16 comprises the method of Example 1, wherein the mask layout portion of the first mask layer is a first mask layout portion of the first mask layer, the mask layout portion of the second mask layer is a first mask layout portion of the second mask layer, the plurality of RET geometries corresponding to the first mask layout portion of the second mask layer is a first plurality of RET geometries, the method further comprising performing RET processing on one or more second mask layout portions of the first mask layer to generate a second plurality of RET geometries corresponding to the one or more second mask layout portions of the first mask layer, wherein the initial conditions for RET processing of the first mask layer further comprises the second plurality of RET geometries corresponding to the one or more second mask layout portions of the first mask layer.

Example 17 comprises the method of Example 1, wherein performing RET processing on the first mask layer comprises performing one or more iterations of an inverse lithography technique (ILT).

Example 18 comprises the method of any one of Examples 1-17, further comprising sending the information representing the first mask layer and the information representing the plurality of RET geometries for the first mask layer to a mask-making tool.

Example 19 comprises the method of any one of Examples 1-18, further comprising, using a mask-making tool, forming a mask based on the information representing the first mask layer and the information representing the plurality of RET geometries for the first mask layer.

Example 20 comprises the method of any one of Examples 1-19, wherein the information representing the first mask layer and the information representing the plurality of RET geometries for the first mask layer are stored in a database storing information representing one or more other mask layers associated with one or more other integrated circuit designs and information representing RET geometries for the one or more other mask layers.

Example 21 comprises the method of Example 1, wherein information representing the mask layout portion of the second mask layer and information representing the plurality of RET geometries corresponding to the mask layout portion of the second mask layer are stored in a database, the database further comprising information representing an additional mask layout portion for an additional mask layer and information representing RET geometries for the additional mask layout portion, the mask layout portion of the first mask layer matching the additional mask layout portion, the method further comprising, if an image object and wafer contour objective error for the mask layout portion of the first mask layer is less than an image object and wafer objective error for the additional mask layout portion: storing, in the database, information representing the mask layout portion of the first mask layer and information representing RET geometries of the plurality of RET geometries for the first mask layer corresponding to the mask layout portion of the first mask layer if an error for one or more image objectives and one or more wafer contour objectives for the mask layout portion of the first mask layer is less than an image object and wafer objective error for the additional mask layout portion; and removing the information representing the additional mask layout portion and information representing RET geometries corresponding to the additional mask layout portion.

Example 22 comprises the method of Example 21, wherein the one or more image objectives comprise an objective indicating a predicted image intensity that is to be met inside an SRAF to prevent photoresist residue formation after photoresist development and/or an objective indicating a predicted image intensity that is to be met between two neighboring SRAFs to prevent loss of a photoresist after development; and wherein the one or more wafer contour objectives comprise: an objective indicating a permissible error between an edge of a SRAF and a corresponding photoresist edge formed on a wafer; an objective indicating a closest permissible distance between photoresist contour edges belonging to a same photoresist contour; or an objective indicating a closest permissible distance between photoresist contour edges belonging to neighboring photoresist contours.

Example 23 comprises the method of Example 21, wherein the database is stored external or remote to a computing system performing the RET processing on the first mask layer.

Example 24 comprises a computing system comprising: one or more processing units; and one or more computer-readable storage media storing computer-executable instructions that, when executed, cause the one or more processing units to perform the method of any one of Examples 1-23.

Example 25 comprises one or more computer-readable storage media storing computer-executable instructions that, when executed, cause one or more computing systems to perform the method of any one of Examples 1-23.

Example 26 comprises a computing system comprising: an initial condition determining means for determining initiation conditions for RET processing of a first mask layer corresponding to an integrated circuit design; one or more processing units; and one or more computer-readable instructions that, when executed, cause the one or more processing units to: perform RET processing on the first mask layer to generate a plurality of RET geometries for the first mask layer; and store information representing the first mask layer and information representing the plurality of RET geometries for the first mask layer.

Example 27 comprises the computing system of Example 26, wherein performing RET processing on the first mask layer comprises performing one or more iterations of an inverse lithography technique (ILT).

Example 28 comprises the computing system of Example 26 or 27, the one or more computer-readable instructions, when executed, to further cause the one or more processing units to send the information representing the first mask layer and the information representing the plurality of RET geometries for the first mask layer to a mask-making tool.

Example 29 comprises the computing system of Example 26 or 27, further comprising a mask-making tool to form a mask based on the information representing the first mask layer and the information representing the plurality of RET geometries for the first mask layer.

1. A method comprising:
identifying a mask layout portion of a first mask layer that matches a mask layout portion of a second mask layer, the first mask layer corresponding to an integrated circuit design, the second mask layer a previously resolution enhancement technique (RET)-processed mask layer;
performing RET processing on the first mask layer to generate a plurality of RET geometries for the first mask layer, initial conditions for RET processing of the first mask layer based on a plurality of RET geometries corresponding to the mask layout portion of the second mask layer; and
storing information representing the first mask layer and information representing the plurality of RET geometries for the first mask layer.

2. The method of claim 1, wherein the plurality of RET geometries corresponding to the mask layout portion of the second mask layer comprises a plurality of sub-resolution assist features (SRAFs), wherein the mask layout portion of the first mask layer is a first mask layout portion of the first mask layer, the mask layout portion of the second mask layer is a first mask layout portion of the second mask layer, the plurality of RET geometries corresponding to the first mask layout portion of the second mask layer is a first plurality of RET geometries, the first plurality of RET geometries comprising a first plurality of SRAFs, the method further comprising:
identifying one or more second mask layout portions of the first mask layer that match one or more second mask layout portions of the second mask layer, second pluralities of RET geometries corresponding to the one or more second mask layout portions of the second mask layer comprising one or more second pluralities of SRAFs; and
determining that a conflict exists between the first plurality of SRAFs and the one or more second pluralities of SRAFs, wherein, to resolve the conflict, the initial conditions for RET processing of the first mask layer are not based on the first plurality of SRAFs and/or at least one of the one or more second pluralities of SRAFs.

3. The method of claim 2, wherein the first plurality of SRAFs conflicts with the one or more second pluralities of SRAFs in that an SRAF of the first plurality of SRAFs overlaps with an SRAF of the one or more second pluralities of SRAFs.

4. The method of claim 2, where the first plurality of SRAFs and the one or more second pluralities of SRAFs define a conflicting set of SRAFs, the method further comprising:
determining an SRAF configuration cost for a plurality of SRAF configurations, individual SRAF configurations of the plurality of SRAF configurations comprising the conflicting set of SRAFs with the first plurality of SRAFs and/or at least one of the one or more second pluralities of SRAFs removed from the conflicting set of SRAFs, the individual SRAF configurations comprising a different set of SRAFs, the SRAF configuration cost for an individual SRAF configuration based on one or more image objectives and one or more wafer contour objectives for the individual SRAF configuration; and
determining an SRAF configuration from the plurality of SRAF configurations having a lowest SRAF configuration cost, wherein the first plurality of SRAFs and/or the one or more second pluralities of SRAFs that RET processing of the first mask layer is not based on the first plurality of SRAFs and/or the one or more second pluralities of SRAFs removed from the conflicting set of SRAFs for the SRAF configuration having the lowest SRAF configuration cost.

5. The method of claim 1, wherein the mask layout portion of the first mask layer is a first mask layout portion of the first mask layer and the mask layout portion of the second mask layer is a first mask layout portion of the second mask layer, the plurality of RET geometries corresponding to the first mask layout portion of the second mask layer is a first plurality of RET geometries, the method further comprising:
identifying a second mask layout portion of the first mask layer that closely matches a second mask layout portion of the second mask layer, wherein the second mask layout portion of the first mask layer closely matches the second mask layout portion of the second mask layer in that at least one edge of a polygon in the second mask layout portion of the first mask layer is spaced a corresponding edge of a corresponding polygon in the second mask layout portion of the second mask layer by a distance within a range of distances; and
generating, by providing information representing the second mask layout portion of the first mask layer to a machine learning model, a second plurality of RET geometries corresponding to the second mask layout portion of the first mask layer, wherein the initial conditions for the RET processing of the first mask layer is further based on the second plurality of RET geometries corresponding to the second mask layout portion of the first mask layer.

6. The method of claim 1, wherein the mask layout portion of the first mask layer is a first mask layout portion of the first mask layer, the mask layout portion of the second mask layer is a first mask layout portion of the second mask layer, the plurality of RET geometries corresponding to the first mask layout portion of the second mask layer is a first plurality of RET geometries, the method further comprising performing RET processing on one or more second mask layout portions of the first mask layer to generate a second plurality of RET geometries corresponding to the one or more second mask layout portions of the first mask layer, wherein the initial conditions for RET processing of the first mask layer further comprises the second plurality of RET geometries corresponding to the one or more second mask layout portions of the first mask layer.

7. The method of claim 1, wherein performing RET processing on the first mask layer comprises performing one or more iterations of an inverse lithography technique (ILT).

8. The method of claim 1, wherein information representing the mask layout portion of the second mask layer and information representing the plurality of RET geometries corresponding to the mask layout portion of the second mask layer are stored in a database, the database further comprising information representing an additional mask layout portion for an additional mask layer and information representing RET geometries for the additional mask layout portion, the mask layout portion of the first mask layer matching the additional mask layout portion, the method further comprising, if an image object and wafer contour objective error for the mask layout portion of the first mask layer is less than an image object and wafer objective error for the additional mask layout portion:
storing, in the database, information representing the mask layout portion of the first mask layer and information representing RET geometries of the plurality of RET geometries for the first mask layer corresponding to the mask layout portion of the first mask layer if an error for one or more image objectives and one or more wafer contour objectives for the mask layout portion of the first mask layer is less than an image object and wafer objective error for the additional mask layout portion; and
removing the information representing the additional mask layout portion and information representing RET geometries corresponding to the additional mask layout portion.

9. One or more computer-readable storage media storing computer-executable instructions that, when executed, cause one or more processing units to:
identify a mask layout portion of a first mask layer that matches a mask layout portion of a second mask layer, the first mask layer corresponding to an integrated circuit design, the second mask layer a previously resolution enhancement technique (RET)-processed mask layer;
perform RET processing on the first mask layer to generate a plurality of RET geometries for the first mask layer, initial conditions for RET processing of the first mask layer based on a plurality of RET geometries corresponding to the mask layout portion of the second mask layer; and
store information representing the first mask layer and information representing the plurality of RET geometries for the first mask layer.

10. The one or more computer-readable storage media of claim 9, wherein the plurality of RET geometries corresponding to the mask layout portion of the second mask layer comprises a plurality of sub-resolution assist features (SRAFs), the mask layout portion of the first mask layer is a first mask layout portion of the first mask layer, the mask layout portion of the second mask layer is a first mask layout portion of the second mask layer, the plurality of RET geometries corresponding to the first mask layout portion of the second mask layer is a first plurality of RET geometries, the first plurality of RET geometries comprising a first plurality of SRAFs, the computer-executable instructions, when executed, to further cause the one or more processing units to:
identify one or more second mask layout portions of the first mask layer that match one or more second mask layout portions of the second mask layer, second pluralities of RET geometries corresponding to the one or more second mask layout portions of the second mask layer comprising one or more second pluralities of SRAFs; and
determine that a conflict exists between the first plurality of SRAFs and the one or more second pluralities of SRAFs, wherein, to resolve the conflict, the initial conditions for RET processing of the first mask layer are not based on the first plurality of SRAFs and/or at least one of the one or more second pluralities of SRAFs.

11. The one or more computer-readable storage media of claim 10, where the first plurality of SRAFs and the one or more second pluralities of SRAFs define a conflicting set of SRAFs, the computer-executable instructions, when executed, to further cause the one or more processing units to:
determine an SRAF configuration cost for a plurality of SRAF configurations, individual SRAF configurations of the plurality of SRAF configurations comprising the conflicting set of SRAFs with the first plurality of SRAFs and/or at least one of the one or more second pluralities of SRAFs removed from the conflicting set of SRAFs, the individual SRAF configurations comprising a different set of SRAFs, the SRAF configuration cost for an individual SRAF configuration based on one or more image objectives and one or more wafer contour objectives for the individual SRAF configuration; and
determine an SRAF configuration from the plurality of SRAF configurations having a lowest SRAF configuration cost, wherein the first plurality of SRAFs and/or the one or more second pluralities of SRAFs that RET processing of the first mask layer is not based on the first plurality of SRAFs and/or the one or more second pluralities of SRAFs removed from the conflicting set of SRAFs for the SRAF configuration having the lowest SRAF configuration cost.

12. The one or more computer-readable storage media of claim 9, wherein the mask layout portion of the first mask layer is a first mask layout portion of the first mask layer and the mask layout portion of the second mask layer is a first mask layout portion of the second mask layer, the plurality of RET geometries corresponding to the first mask layout portion of the second mask layer is a first plurality of RET geometries, the computer-executable instructions, when executed, to further cause the one or more processing units to:
identify a second mask layout portion of the first mask layer that closely matches a second mask layout portion of the second mask layer, wherein the second mask layout portion of the first mask layer closely matches the second mask layout portion of the second mask layer in that at least one edge of a polygon in the second mask layout portion of the first mask layer is spaced a corresponding edge of a corresponding polygon in the second mask layout portion of the second mask layer by a distance within a range of distances; and
generate, by providing information representing the second mask layout portion of the first mask layer to a machine learning model, a second plurality of RET geometries corresponding to the second mask layout portion of the first mask layer, wherein the initial conditions for the RET processing of the first mask layer is further based on the second plurality of RET geometries corresponding to the second mask layout portion of the first mask layer.

13. The one or more computer-readable storage media of claim 9, wherein the mask layout portion of the first mask layer is a first mask layout portion of the first mask layer, the mask layout portion of the second mask layer is a first mask layout portion of the second mask layer, the plurality of RET geometries corresponding to the first mask layout portion of the second mask layer is a first plurality of RET geometries, the computer-executable instructions, when executed, further to cause the one or more processing units to perform RET processing on one or more second mask layout portions of the first mask layer to generate a second plurality of RET geometries corresponding to the one or more second mask layout portions of the first mask layer, wherein the initial conditions for RET processing of the first mask layer further comprises the second plurality of RET geometries corresponding to the one or more second mask layout portions of the first mask layer.

14. The one or more computer-readable storage media of claim 9, wherein to perform RET processing on the first mask layer comprises performing one or more iterations of an inverse lithography technique (ILT).

15. The one or more computer-readable storage media of claim 9, wherein information representing the mask layout portion of the second mask layer and information representing the plurality of RET geometries corresponding to the mask layout portion of the second mask layer are stored in a database, the database further comprising information representing an additional mask layout portion for an additional mask layer and information representing RET geometries for the additional mask layout portion, the mask layout portion of the first mask layer matching the additional mask layout portion, the computer-executable instructions, when executed, to further cause the one or more processing units to, if an image object and wafer contour objective error for the mask layout portion of the first mask layer is less than an image object and wafer objective error for the additional mask layout portion:
store, in the database, information representing the mask layout portion of the first mask layer and information representing RET geometries of the plurality of RET geometries for the first mask layer corresponding to the mask layout portion of the first mask layer if an error for one or more image objectives and one or more wafer contour objectives for the mask layout portion of the first mask layer is less than an image object and wafer objective error for the additional mask layout portion; and
remove the information representing the additional mask layout portion and information representing RET geometries corresponding to the additional mask layout portion.

16. A computing system comprising:
one or more processing units; and
one or more computer-readable storage media storing computer-executable instructions that, when executed, cause the one or more processing units to:
identify a mask layout portion of a first mask layer that matches a mask layout portion of a second mask layer, the first mask layer corresponding to an integrated circuit design, the second mask layer a previously resolution enhancement technique (RET)-processed mask layer;
perform RET processing on the first mask layer to generate a plurality of RET geometries for the first mask layer, initial conditions for RET processing of the first mask layer based on a plurality of RET geometries corresponding to the mask layout portion of the second mask layer; and
store information representing the first mask layer and information representing the plurality of RET geometries for the first mask layer.

17. The computing system of claim 16, wherein the plurality of RET geometries corresponding to the mask layout portion of the second mask layer comprises a plurality of sub-resolution assist features (SRAFs), the mask layout portion of the first mask layer is a first mask layout portion of the first mask layer, the mask layout portion of the second mask layer is a first mask layout portion of the second mask layer, the plurality of RET geometries corresponding to the first mask layout portion of the second mask layer is a first plurality of RET geometries, the first plurality of RET geometries comprising a first plurality of SRAFs, the computer-executable instructions, when executed, to further cause the one or more processing units to:
identify one or more second mask layout portions of the first mask layer that match one or more second mask layout portions of the second mask layer, second pluralities of RET geometries corresponding to the one or more second mask layout portions of the second mask layer comprising one or more second pluralities of SRAFs; and
determine that a conflict exists between the first plurality of SRAFs and the one or more second pluralities of SRAFs, wherein, to resolve the conflict, the initial conditions for RET processing of the first mask layer are not based on the first plurality of SRAFs and/or at least one of the one or more second pluralities of SRAFs.

18. The computing system of claim 17, where the first plurality of SRAFs and the one or more second pluralities of SRAFs define a conflicting set of SRAFs, the computer-executable instructions, when executed, to further cause the one or more processing units to:
determine an SRAF configuration cost for a plurality of SRAF configurations, individual SRAF configurations of the plurality of SRAF configurations comprising the conflicting set of SRAFs with the first plurality of SRAFs and/or at least one of the one or more second pluralities of SRAFs removed from the conflicting set of SRAFs, the individual SRAF configurations comprising a different set of SRAFs, the SRAF configuration cost for an individual SRAF configuration based on one or more image objectives and one or more wafer contour objectives for the individual SRAF configuration; and
determine an SRAF configuration from the plurality of SRAF configurations having a lowest SRAF configuration cost, wherein the first plurality of SRAFs and/or the one or more second pluralities of SRAFs that RET processing of the first mask layer is not based on the first plurality of SRAFs and/or the one or more second pluralities of SRAFs removed from the conflicting set of SRAFs for the SRAF configuration having the lowest SRAF configuration cost.

19. The computing system of claim 16, wherein the mask layout portion of the first mask layer is a first mask layout portion of the first mask layer and the mask layout portion of the second mask layer is a first mask layout portion of the second mask layer, the plurality of RET geometries corresponding to the first mask layout portion of the second mask layer is a first plurality of RET geometries, the computer-executable instructions, when executed, to further cause the one or more processing units to:
identify a second mask layout portion of the first mask layer that closely matches a second mask layout portion of the second mask layer, wherein the second mask layout portion of the first mask layer closely matches the second mask layout portion of the second mask layer in that at least one edge of a polygon in the second mask layout portion of the first mask layer is spaced a corresponding edge of a corresponding polygon in the second mask layout portion of the second mask layer by a distance within a range of distances; and
generate, by providing information representing the second mask layout portion of the first mask layer to a machine learning model, a second plurality of RET geometries corresponding to the second mask layout portion of the first mask layer, wherein the initial conditions for the RET processing of the first mask layer is further based on the second plurality of RET geometries corresponding to the second mask layout portion of the first mask layer.

20. The computing system of claim 16, wherein the mask layout portion of the first mask layer is a first mask layout portion of the first mask layer, the mask layout portion of the second mask layer is a first mask layout portion of the second mask layer, the plurality of RET geometries corresponding to the first mask layout portion of the second mask layer is a first plurality of RET geometries, the computer-executable instructions, when executed, to further cause the one or more processing units to perform RET processing on one or more second mask layout portions of the first mask layer to generate a second plurality of RET geometries corresponding to the one or more second mask layout portions of the first mask layer, wherein the initial conditions for RET processing of the first mask layer further comprises the second plurality of RET geometries corresponding to the one or more second mask layout portions of the first mask layer.
